(19) United States
(12) Patent Application Publication
(10) Pub. No.: US 2019/0243187 A1
(43) Pub. Date: Aug. 8, 2019

(54) DISPLAY MODULE

(71) Applicants: HannStar Display (Nanjing) Corporation, Nanjing (CN); HannStar Display Corporation, Taipei City (TW)

(72) Inventor: Chun-Pin LIU, Taipei City (TW)

(21) Appl. No.: 16/242,014

(22) Filed: Jan. 8, 2019

(30) Foreign Application Priority Data
Feb. 6, 2018 (CN) 201810119532.5

(51) Int. Cl. G02F 1/1335; H05K 1/18

(52) U.S. Cl. CPC G02F 1/133603; G02F 1/133606; H05K 1/189; G02F 1/133514; G02F 2001/133541; G02F 1/133611; H05K 2201/10106; H05K 2201/10136; G02F 1/133528

(57) ABSTRACT

A display module includes a thin film transistor (TFT) substrate, a color filter (CF) substrate, a flexible printed circuit (FPC), and a Mini-LED layer. The TFT substrate has a light incident surface and a light emitting surface opposite to the light incident surface. A connection portion is provided by the light incident surface. The CF substrate is disposed on the light incident surface. The FPC includes a bonding portion and a body portion. The bonding portion is electrically connected to the connection portion. The body portion extends along the light incident surface. The Mini-LED layer is disposed on the body portion and positioned between the CF substrate and the body portion. The Mini-LED layer has plural Mini LEDs. Each of the Mini LEDs has a chip. A size of the chip is between 15 μm to 150 μm.

### RELATED APPLICATIONS

This application claims priority to China Application Serial Number 201810119532.5 filed Feb. 6, 2018, which is herein incorporated by reference.

### BACKGROUND

### Field of Invention

The present invention relates to a display module. More particularly, the present invention relates to a frameless display module.

### Description of Related Art

Due to the requirements of high screen-to-body ratio, the current design of the display module tends to a narrow-framed design or even a frameless and full-screen design, thereby improving the screen-to-body ratio of the cell phone. The cell phone can expand the display area without increasing the size of the cell phone, thereby realizing a better balance of the size of the cell phone and the screen size of the cell phone. Moreover, the user can operate the cell phone by using only one hand even in the larger screen size. However, the current design of the display module is hard to meet the requirements of the narrow-framed design or even the frameless and full-screen design. Therefore, a design of the display module to realize the frameless display module is necessary.

Micro LED is a next generation display technology, but Micro LED still has its development difficulties at current stage because the technologies for LEDs miniaturization and mass transferring still need to be resolved. Before the commercialization of Micro LED, Mini LED is a display technology which can be realized in current stage. The backlight source of the conventional thin film transistor (TFT) liquid crystal displays (LCDs) needs about several to several dozen LEDs in accordance with the panel size. The chip size of these LEDs is about 200 μm to 300 μm. Micro LED display needs millions of Micro LEDs, and the chip size of these Micro LEDs is about 15 μm, therefore Micro LED display is hard to realize. The LCDs utilizing Mini LED only need thousands or tens of thousands of Mini LEDs, and the chip size of these Mini LEDs is between the chip size of LEDs and the chip size of Micro LEDs. Furthermore, the existing equipment can be modified to manufacture the LCDs utilizing Mini LED, thereby saving the cost. Therefore, the LCDs utilizing Mini LED is a potential technology.

### SUMMARY

An object of the present invention is to provide a display module which realizes a frameless and full-screen design and realizes a thinning and direct-type display module by using the Mini LEDs.

According to the object of the present invention, a display module is provided. The display module includes a thin film transistor (TFT) substrate, a color filter (CF) substrate, a flexible printed circuit (FPC), and a Mini-LED layer. The TFT substrate has a light incident surface and a light emitting surface opposite to the light incident surface. There is a connection portion provided by the light incident surface. The CF substrate is disposed on the light incident surface of the TFT substrate. The CF substrate has a first surface and a second surface opposite to the first surface. The first surface is nearer to the light incident surface than the second surface. The FPC includes a bonding portion and a body portion. The bonding portion of the FPC is electrically connected to the connection portion of the TFT substrate. The body portion of the FPC extends along the second surface of the CF substrate. The Mini-LED layer is disposed on an upper surface of the body portion of the FPC and positioned between the CF substrate and the body portion of the FPC. The Mini-LED layer has plural Mini LEDs. Each of the Mini LEDs has a chip. A size of the chip is between 15 μm to 150 μm.

According to some embodiments of the present invention, the display module further includes an upper polarizer, a lower polarizer, and a diffuser plate. The upper polarizer is attached on the light emitting surface of the TFT substrate. The lower polarizer is attached on the second surface of the CF substrate. The diffuser plate is disposed on the Mini-LED layer and positioned between the lower polarizer and the Mini-LED layer.

According to some embodiments of the present invention, a thickness of the diffuser plate is between 0.2 mm to 1.35 mm.

According to some embodiments of the present invention, the display module further includes an optical film layer. The optical film layer is disposed between the diffuser plate and the lower polarizer. The optical film layer at least includes a diffusion film, a brightness enhancement film, or a quantum dot film.

According to some embodiments of the present invention, a portion of the upper surface of the body portion of the FPC which is not covered by the Mini LEDs is coated with a reflective material.

According to the object of the present invention, another display module is provided. The display module includes a first substrate, a second substrate, and a FPC. The first substrate has a light incident surface and a light emitting surface opposite to the light incident surface. A first surface of the second substrate is attached on the light incident surface of the first substrate. A surface area of the light incident surface of the first substrate is larger than a surface area of the first surface of the second substrate. A connection portion is provided by a surface of the first substrate which faces the second substrate and is not attached by the second substrate. The FPC includes a bonding portion and a body portion. The bonding portion of the FPC is electrically connected to the connection portion of the first substrate. The body portion of the FPC extends along the first substrate at a side towards the second substrate.

According to some embodiments of the present invention, the display module further includes a Mini-LED layer. The Mini-LED layer is disposed on an upper surface of the body portion of the FPC and positioned between the second substrate and the body portion of the FPC. The Mini-LED layer has plural Mini LEDs. Each of the Mini LEDs has a chip. A size of the chip is between 15 μm to 150 μm.

According to some embodiments of the present invention, the display module further includes an upper polarizer, a lower polarizer, and a diffuser plate. The upper polarizer is attached on the first substrate. The lower polarizer is attached on the second substrate. The first substrate and the second substrate are positioned between the upper polarizer and the lower polarizer. The diffuser plate is disposed on the Mini-LED layer and positioned between the lower polarizer and the Mini-LED layer.

According to some embodiments of the present invention, a thickness of the diffuser plate is between 0.2 mm to 1.35 mm. A haze value of the diffuser plate is lower than 85%.

According to some embodiments of the present invention, the display module further includes an optical film layer. The optical film layer is disposed between the diffuser plate and the lower polarizer. The optical film layer at least includes a diffusion film, a brightness enhancement film, or a quantum dot film.

According to some embodiments of the present invention, a portion of the upper surface of the body portion of the FPC which is not covered by the Mini LEDs is coated with a reflective material.

According to some embodiments of the present invention, the upper polarizer is an anti-glare polarizer. A haze value of the upper polarizer is greater than or equal to 12%.

According to some embodiments of the present invention, the upper polarizer is a circular polarization polarizer.

### BRIEF DESCRIPTION OF THE DRAWINGS

The invention can be more fully understood by reading the following detailed description of the embodiment, with reference made to the accompanying drawings as follows.

FIG. 1 is a cross-sectional view of a structure of a display module according to an embodiment of the present invention.

FIG. 2 is a top view and a cross-sectional view illustrating an arrangement relationship of a Mini-LED layer and a body portion of a FPC according to an embodiment of the present invention.

FIG. 3 is a cross-sectional view of a structure of a conventional display module.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. Moreover, any device with equivalent functions that is produced from a structure formed by a recombination of elements shall fall within the scope of the present invention. Additionally, the drawings are only illustrative and are not drawn to actual size. In addition, the using of “first”, “second”, “third”, etc. in the specification should be understood for identify units or data described by the same terminology, but is not referred to particular order or sequence.

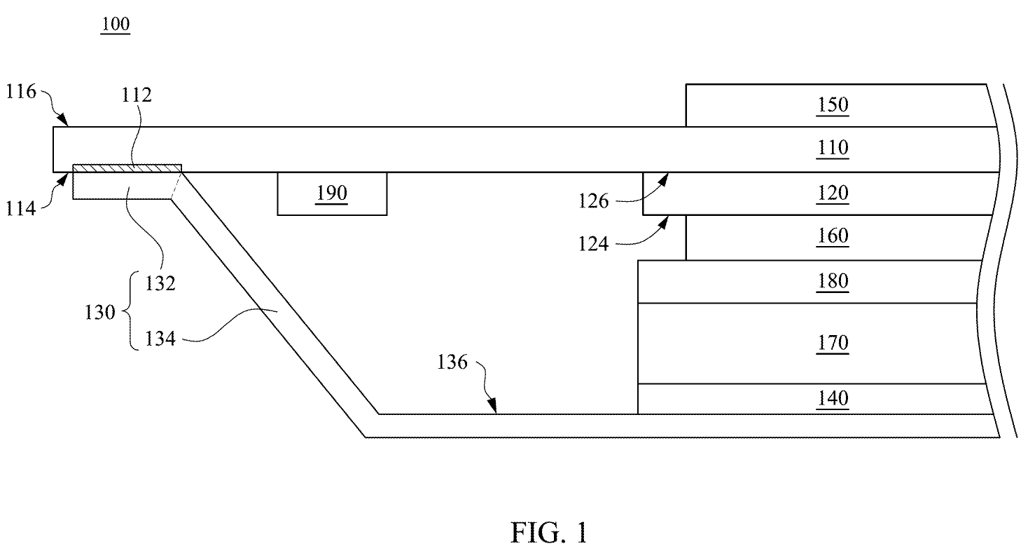

FIG. 1 is a cross-sectional view of a structure of a display module 100 according to an embodiment of the present invention. The display module 100 includes a first substrate 110, a second substrate 120, and a FPC 130. The first substrate 110 has a light incident surface 114 and a light emitting surface 116 opposite to the light incident surface 114. A first surface 126 of the second substrate 120 is attached on the light incident surface 114 of the first substrate 110. A surface area of the light incident surface 114 of the first substrate 110 is larger than a surface area of the first surface 126 of the second substrate 120. A connection portion 112 is provided by a surface of the first substrate 110 which faces the second substrate 120 and is not attached by the second substrate 120. The FPC 130 includes a bonding portion 132 and a body portion 134. The bonding portion 132 of the FPC 130 is electrically connected to the connection portion 112 of the first substrate 110. The body portion 134 of the FPC 130 extends along the first substrate 110 at a side towards the second substrate 120. In the embodiment of the present invention, the connection portion 112 is a bonding pad disposed on the first substrate 110. The first substrate 110 is connected to the bonding portion 132 of the FPC 130 through the bonding pad.

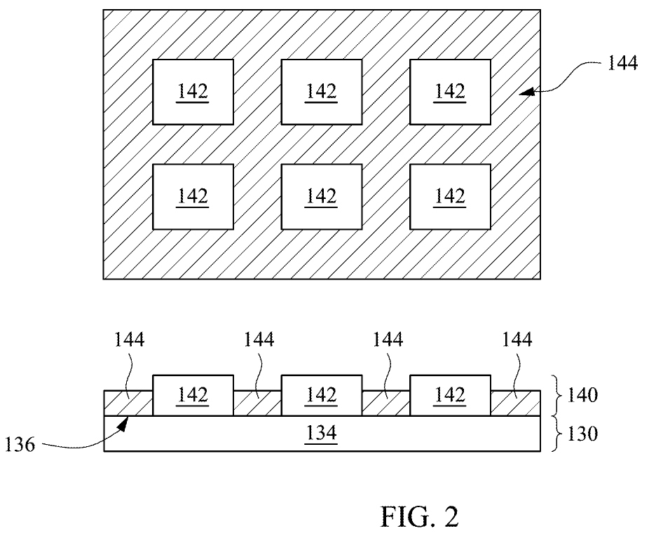

Referring to FIG. 1, the display module 100 further includes a Mini-LED layer 140. The Mini-LED layer 140 is disposed on an upper surface 136 of the body portion 134 of the FPC 130. The Mini-LED layer 140 is positioned between the second substrate 120 and the body portion 134 of the FPC 130. FIG. 2 is a top view and a cross-sectional view illustrating an arrangement relationship of the Mini-LED layer 140 and the body portion 134 of a FPC 130 according to an embodiment of the present invention, in which the upper portion of FIG. 2 is the top view, and the lower portion of FIG. 2 is the cross-sectional view. The Mini-LED layer 140 has plural Mini LEDs 142. Each of the Mini LEDs 142 has a chip, and the size of the chip is between 15 μm to 150 μm.

Referring to FIG. 1, the display module 100 further includes an upper polarizer 150, a lower polarizer 160, and a diffuser plate 170. The upper polarizer 150 is attached on the first substrate 110. The lower polarizer 160 is attached on the second substrate 120. The first substrate 110 and the second substrate 120 are positioned between the upper polarizer 150 and the lower polarizer 160. The diffuser plate 170 is disposed on the Mini-LED layer 140. The diffuser plate 170 is positioned between the lower polarizer 160 and the Mini-LED layer 140. In the embodiment of the present invention, the Mini-LED layer 140 and the diffuser plate 170 are pasted and fixed by using the double-sided border adhesive tape.

It is noted that, in the embodiment of the present invention, the thickness of the diffuser plate 170 is between 0.2 mm to 1.35 mm. In contrast, the thickness of the diffuser plate used in the conventional LCDs is between 1.5 mm to 2 mm. Specifically, the diffuser plate 170 of the present invention has a thinner thickness than the diffuser plate used in the conventional LCDs because comparing to the conventional LCDs, the chips of Mini LEDs have smaller size, and thus the amount of Mini LEDs is greater in the same area and Mini LEDs have better uniformity, so that the diffuser plate 170 may have a thinner thickness. In the embodiment of the present invention, the haze value of the diffuser plate 170 is lower than 85%. In contrast, the haze value of the diffuser plate used in the conventional LCDs is between 85% and 95%. Specifically, the diffuser plate 170 of the present invention has the smaller haze value than the diffuser plate used in the conventional LCDs. In another embodiment of the present invention, the display module 100 may not include the diffuser plate 170 because the display module 100 utilizes Mini LEDs.

Referring to FIG. 1, the display module 100 further includes an optical film layer 180. The optical film layer 180 is disposed between the diffuser plate 170 and the lower polarizer 160. In the embodiment of the present invention, the optical film layer 180 at least includes a diffusion film, a brightness enhancement film, or a quantum dot film. In the embodiment of the present invention, the optical film layer 180 is pasted and fixed between the diffuser plate 170 and the lower polarizer 160 by using the double-sided border adhesive tape.

In the embodiment of the present invention, the direct-type display module is realized by utilizing the Mini-LED layer 140, the diffuser plate 170, and the optical film layer 180, etc. Referring to FIG. 2, in the embodiment of the present invention, a portion of the upper surface 136 of the body portion 134 of the FPC 130 which is not covered by the Mini LEDs 142 is coated with a reflective material 144, such as white paint or other metal material (e.g. sliver). It is worth mentioning that the present invention realizes the function of the reflective sheet by coating the reflective material 144. Specifically, the thickness of the diffuser plate 170 of the present invention is thinner than the thickness of the diffuser plate used in the conventional LCDs, and the present invention does not need to provide the reflective sheet, and thus the present invention realizes a thinning and direct-type display module.

Referring to FIG. 1, in the embodiment of the present invention, the first substrate 110 is a thin film transistor (TFT) substrate. The first substrate 110 has the light incident surface 114 and the light emitting surface 116 opposite to the light incident surface 114. The connection portion 112 is disposed at a side of the light incident surface 114 of the first substrate 110. In the embodiment of the present invention, the second substrate 120 is a color filter (CF) substrate. The second substrate 120 is disposed on the light incident surface 114 of the first substrate 110. The second substrate 120 has the first surface 126 and the second surface 124 opposite to the first surface 126. The first surface 126 of the second substrate 120 is nearer to the light incident surface 114 of the first substrate 110 than the second surface 124 of the second substrate 120. The body portion 134 of the FPC 130 extends along the second surface 124 of the second substrate 120.

Referring to FIG. 1, the display module 100 further includes a controller chip 190. The controller chip 190 is disposed on a surface of the first substrate 110 (i.e. the TFT substrate) which faces the second substrate 120 (i.e. the CF substrate) and is not attached by the second substrate 120. In the embodiment of the present invention, the FPC 130 includes a TFT LCD FPC and a light bar FPC. The FPC 130 is configured to connect the electrical signals of the controller chip 190.

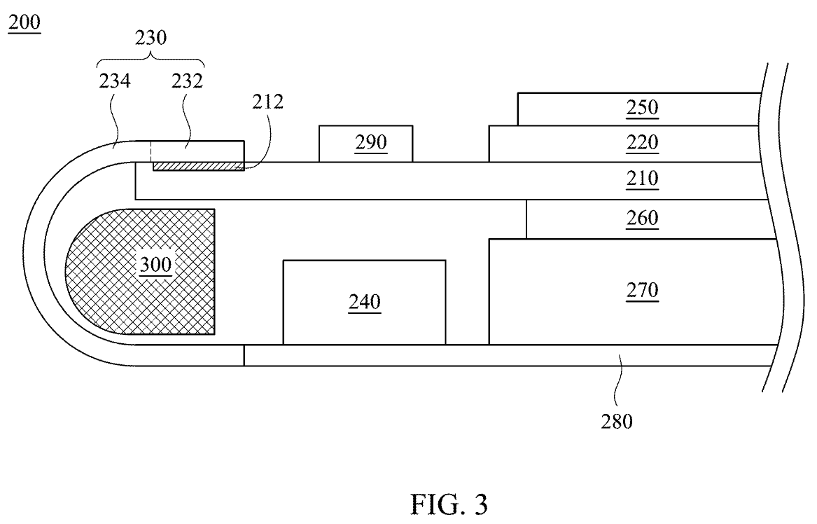

FIG. 3 is a cross-sectional view of a structure of a conventional display module 200. The conventional display module 200 includes a TFT substrate 210, a CF substrate 220, a TFT LCD FPC 230, plural LEDs 240, an upper polarizer 250, a lower polarizer 260, a light guiding unit 270 (e.g. a diffuser plate, a light guide plate, a reflective sheet, etc.), a backlight FPC 280, and a controller chip 290. As shown in FIG. 3, the LEDs 240 are electrically disposed on the backlight FPC 280. A bonding portion 232 of the TFT LCD FPC 230 is electrically connected to the connection portion 212 disposed on a surface of the TFT substrate 210. A body portion 234 of the TFT LCD FPC 230 is folded over the frame 300 and then electrically connected to the backlight FPC 280.

In the embodiment of the present invention, the body portion 134 of the FPC 130 extends along the first substrate 110 (i.e. the TFT substrate) at a side towards the second substrate 120 (i.e. the CF substrate). In contrast, for the conventional display module 200, the TFT LCD FPC 230 need to be folded to cross over the frame 300, and thus may be electrically connected to the backlight FPC 280, so that the implement of the narrow-framed display module is difficult. Specifically, the FPC 130 of the present invention incorporates the TFT LCD FPC and the backlight FPC, and the display module 100 of the present invention eliminates the frame, and the FPC 130 of the present invention does not need to be folded, and the body portion 134 of the FPC 130 of the present invention directly extends along the first substrate 110 at a side towards the second substrate 120. Therefore, the display module 100 of the present invention may realize a frameless design.

In the embodiment of the present invention, the back light enters from the second substrate 120 (i.e. the CF substrate) and emits from the first substrate 110 (i.e. the TFT substrate), and thus the visual feeling may be affected due to the metal reflection of the TFT substrate. In the embodiment of the present invention, the upper polarizer 150 may be an anti-glare polarizer. The anti-glare polarizer is configured to improve the visual feeling of the embodiment of the present invention. The haze value of the anti-glare polarizer is greater than or equal to 12%. In the other embodiment of the present invention, the upper polarizer 150 may be a circular polarization polarizer to reduce the effect due to the metal reflection of the TFT substrate. The circular polarization polarizer is configured to improve the visual feeling of the embodiment of the present invention.

To sum up, the FPC of the display module of the embodiment of the present invention does not need to be folded and then crossed over the frame, thereby connecting to the backlight FPC. Therefore, the embodiment of the present invention may realize the frameless and full-screen design. Furthermore, the embodiment of the present invention may realize a thinning and direct-type display module by using the Mini LEDs.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A display module, comprising:
a thin film transistor (TFT) substrate having a light incident surface and a light emitting surface opposite to the light incident surface, wherein a connection portion is provided by the light incident surface;
a color filter (CF) substrate disposed on the light incident surface of the TFT substrate, wherein the CF substrate has a first surface and a second surface opposite to the first surface, wherein the first surface is nearer to the light incident surface than the second surface;
a flexible printed circuit (FPC) comprising a bonding portion and a body portion, wherein the bonding portion of the FPC is electrically connected to the connection portion of the TFT substrate, wherein the body portion of the FPC extends along the second surface of the CF substrate; and
a Mini-LED layer disposed on an upper surface of the body portion of the FPC and positioned between the CF substrate and the body portion of the FPC, wherein the Mini-LED layer has a plurality of Mini LEDs, wherein each of the Mini LEDs has a chip, wherein a size of the chip is between 15 μm to 150 μm.

2. The display module of claim 1, further comprising:
an upper polarizer attached on the light emitting surface of the TFT substrate;
a lower polarizer attached on the second surface of the CF substrate; and
a diffuser plate disposed on the Mini-LED layer and positioned between the lower polarizer and the Mini-LED layer.

3. The display module of claim 2, wherein a thickness of the diffuser plate is between 0.2 mm to 1.35 mm.

4. The display module of claim 2, further comprising:
an optical film layer disposed between the diffuser plate and the lower polarizer, wherein the optical film layer at least comprises a diffusion film, a brightness enhancement film, or a quantum dot film.

5. The display module of claim 1, wherein a portion of the upper surface of the body portion of the FPC which is not covered by the Mini LEDs is coated with a reflective material.

6. A display module, comprising:
a first substrate having a light incident surface and a light emitting surface opposite to the light incident surface;
a second substrate, wherein a first surface of the second substrate is attached on the light incident surface of the first substrate, wherein a surface area of the light incident surface of the first substrate is larger than a surface area of the first surface of the second substrate, wherein a connection portion is provided by a surface of the first substrate which faces the second substrate and is not attached by the second substrate; and
a FPC comprising a bonding portion and a body portion, wherein the bonding portion of the FPC is electrically connected to the connection portion of the first substrate, wherein the body portion of the FPC extends along the first substrate at a side towards the second substrate.

7. The display module of claim 6, further comprising:
a Mini-LED layer disposed on an upper surface of the body portion of the FPC and positioned between the second substrate and the body portion of the FPC, wherein the Mini-LED layer has a plurality of Mini LEDs, wherein each of the Mini LEDs has a chip, wherein a size of the chip is between 15 μm to 150 μm.

8. The display module of claim 7, further comprising:
an upper polarizer attached on the first substrate;
a lower polarizer attached on the second substrate, wherein the first substrate and the second substrate are positioned between the upper polarizer and the lower polarizer; and
a diffuser plate disposed on the Mini-LED layer and positioned between the lower polarizer and the Mini-LED layer.

9. The display module of claim 8, wherein a thickness of the diffuser plate is between 0.2 mm to 1.35 mm, wherein a haze value of the diffuser plate is lower than 85%.

10. The display module of claim 8, further comprising:
an optical film layer disposed between the diffuser plate and the lower polarizer, wherein the optical film layer at least comprises a diffusion film, a brightness enhancement film, or a quantum dot film.

11. The display module of claim 7, wherein a portion of the upper surface of the body portion of the FPC which is not covered by the Mini LEDs is coated with a reflective material.

12. The display module of claim 8, wherein the upper polarizer is an anti-glare polarizer, wherein a haze value of the upper polarizer is greater than or equal to 12%.

13. The display module of claim 8, wherein the upper polarizer is a circular polarization polarizer.
